(19) United States
(12) Patent Application Publication
(10) Pub. No.: US 2024/0162101 A1
(43) Pub. Date: May 16, 2024

(54) ELECTRONIC PACKAGE AND MANUFACTURING METHOD THEREOF

(71) Applicant: SILICONWARE PRECISION INDUSTRIES CO., LTD., Taichung (TW)

(72) Inventor: Yung-Ta LI, Taichung (TW)

(73) Assignee: SILICONWARE PRECISION INDUSTRIES CO., LTD., Taichung (TW)

(21) Appl. No.: 18/190,344

(22) Filed: Mar. 27, 2023

(30) Foreign Application Priority Data
Nov. 11, 2022 (TW) 111143241

(51) Int. Cl. H01L 23/16; H01L 21/56; H01L 23/00; H01L 23/31; H01L 25/16

(52) U.S. Cl. CPC H01L 23/16; H01L 21/568; H01L 23/3128; H01L 23/3185; H01L 24/19; H01L 24/20; H01L 25/16; H01L 21/561; H01L 24/95; H01L 2224/19; H01L 2224/211; H01L 2224/214; H01L 2224/95001

(57) ABSTRACT

An electronic package includes a first electronic element and a dummy die embedded in an encapsulation layer, where the dummy die is used to prevent a warpage caused by the mismatch of coefficient of thermal expansion (CTE) between the encapsulation layer and the first electronic element in the manufacturing process of large full-panel.

### BACKGROUND

### 1. Technical Field

The present disclosure relates to a semiconductor device, and more particularly, to an electronic package of flip-chip packaging type and a manufacturing method thereof.

### 2. Description of Related Art

With the evolution of technology, the demand trend of electronic products is moving towards heterogeneous integration, and for this reason, the multi-chip modules (MCMs)/multi-chip packages (MCPs) are gradually emerging.

In a semiconductor package 1 shown in FIG. 1, a plurality of semiconductor chips 11 are bonded onto a circuit structure 16, and the semiconductor chips 11 are covered by an encapsulant 15. The circuit structure 16 is disposed on a package substrate 10 via a plurality of conductive elements 17, and the package substrate 10 can be disposed onto a circuit board (not shown) via a plurality of solder balls 19. By packaging the plurality of semiconductor chips 11 into a single structure, the semiconductor package 1 can have more I/O, greatly increase the computing power of the processor and reduce the latency of signal transmission so as to be applied to high-end products with high-density circuits/high transmission speed/high number of stacked layers/large-sized design.

However, during the packaging process of the conventional semiconductor package 1, the encapsulant 15 is a panel with a wafer form, and when the encapsulant 15 is subjected to a temperature cycle or stress change such as undergoing a reflow oven or the process or test of dropping, the encapsulant 15 is likely to be warped due to the mismatch of the coefficient of thermal expansion (CTE) between the encapsulant 15 and the semiconductor chips 11, causing cracks between the semiconductor chips 11 and the encapsulant 15, so that the semiconductor chips 11 are broken and the product yield is low.

Therefore, there is a need for a solution that addresses the aforementioned shortcomings in the prior art.

### SUMMARY

In view of the aforementioned shortcomings of the prior art, the present disclosure provides an electronic package, which comprises: an encapsulation layer having a first surface and a second surface opposing the first surface; a first electronic element embedded in the encapsulation layer, wherein the first electronic element has an active surface and an inactive surface opposing the active surface, wherein the active surface has a plurality of conductors, and surfaces of the conductors are flush with the first surface of the encapsulation layer; a first bonding layer embedded in the encapsulation layer and bonded on the inactive surface, wherein an outer surface of the first bonding layer is flush with the second surface of the encapsulation layer; a dummy die embedded in the encapsulation layer and spaced apart from the first electronic element, wherein a surface of the dummy die is flush with the first surface of the encapsulation layer; a second bonding layer embedded in the encapsulation layer and bonded on the dummy die, wherein an outer surface of the second bonding layer is flush with the second surface of the encapsulation layer, wherein a thickness of the first bonding layer is less than a thickness of the second bonding layer; and a circuit structure disposed on the first surface of the encapsulation layer and electrically connected to the first electronic element.

The present disclosure further provides a method of manufacturing an electronic package, the method comprises: disposing a first electronic element on a carrier via a first bonding layer, and disposing a dummy die on the carrier via a second bonding layer, the first electronic element and the dummy die being spaced apart from each other, wherein the first electronic element has an active surface and an inactive surface opposing the active surface, the active surface has a plurality of conductors, and the first electronic element is bonded with the first bonding layer by the inactive surface of the first electronic element, wherein a thickness of the first bonding layer is less than a thickness of the second bonding layer, wherein a height of the first electronic element relative to the carrier is less than or equal to a height of the dummy die relative to the carrier; forming an encapsulation layer on the carrier, wherein the first electronic element and the dummy die are covered by the encapsulation layer, wherein the encapsulation layer has a first surface and a second surface opposing the first surface, and the encapsulation layer is bonded onto the carrier with the second surface of the encapsulation layer, wherein end surfaces of the plurality of conductors and a surface of the dummy die are flush with the first surface of the encapsulation layer; forming a circuit structure on the first surface of the encapsulation layer, wherein the circuit structure is electrically connected to the conductors of the first electronic element and free from being electrically connected to the dummy die; and removing the carrier, wherein an outer surface of the first bonding layer and an outer surface of the second bonding layer are flush with the second surface of the encapsulation layer.

In the aforementioned electronic package and method, the carrier is in contact with and bonded to the second surface of the encapsulation layer, the first bonding layer and the second bonding layer via a dielectric protection layer.

In the aforementioned electronic package and method, a total thickness of the dummy die and the second bonding layer is equal to a total thickness of the first electronic element and the first bonding layer.

In the aforementioned electronic package and method, the present disclosure further comprises disposing a second electronic element on the circuit structure, wherein the second electronic element is electrically connected to the circuit structure. For example, the second electronic element is a bridge element for electrically bridging the first electronic element and another electronic element electrically connected to the circuit structure via the circuit structure.

Furthermore, the present disclosure may comprise forming conductive pillars on the circuit structure, wherein the conductive pillars are electrically connected to the circuit structure. The present disclosure also comprises covering the conductive pillars and the second electronic element by a packaging layer, wherein end surfaces of the conductive pillars are flush with a surface of the packaging layer and exposed from the packaging layer. The present disclosure also comprises forming a routing structure on the packaging layer, wherein the routing structure is electrically connected to the conductive pillars. The present disclosure further comprises forming a plurality of conductive elements on the routing structure.

In the aforementioned electronic package and method, the present disclosure further comprises forming a plurality of conductive elements on the circuit structure.

As can be understood from the above, in the electronic package and manufacturing method thereof according to the present disclosure, the configuration of the dummy die is used to suppress the warpage caused by the mismatch of CTE between the encapsulation layer and the first electronic element, so the present disclosure can prevent the carrier of large full-panel or the encapsulation layer from warping.

Further, since the thickness of the second bonding layer is greater than the thickness of the first bonding layer, an amount of the encapsulation layer is reduced to reduce the volume ratio of the encapsulation layer, thereby further improving the anti-warping effect.

Also, since the total thickness of the dummy die and the second bonding layer is not less than (e.g., is greater than or equal to) the total thickness of the first electronic element and the first bonding layer, the surface of the silicon material with better surface roughness of the dummy die is exposed after the encapsulation layer is subjected to the leveling process, so as to improve the coating condition of the circuit structure stacked on the surface of the dummy die in the subsequent process and effectively improve the product reliability.

### BRIEF DESCRIPTION OF THE DRAWINGS

FIG. 1 is a schematic cross-sectional view of a conventional semiconductor package.

FIG. 2A-1, FIG. 2B, FIG. 2C and FIG. 2D are schematic cross-sectional views illustrating a method of manufacturing an electronic package according to a first embodiment of the present disclosure.

FIG. 2A-2 is a schematic cross-sectional view illustrating another manufacturing method of FIG. 2A-1.

FIG. 2A-3 is a schematic top view of FIG. 2A-1.

FIG. 2E-1 is a schematic cross-sectional view of a subsequent process of FIG. 2D.

FIG. 2E-2 is a schematic cross-sectional view showing another aspect of FIG. 2E-1.

FIG. 3A to FIG. 3G are schematic cross-sectional views illustrating a method of manufacturing an electronic package according to a second embodiment of the present disclosure.

FIG. 3H is a schematic cross-sectional view of a subsequent process of FIG. 3G.

FIG. 4 is a schematic cross-sectional view of a subsequent process of FIG. 2E-2.

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios and sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes, or adjustments to the structures, ratios, or sizes are construed as falling within the scope covered by the technical contents disclosed herein. Meanwhile, terms such as “on,” “above,” “over” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

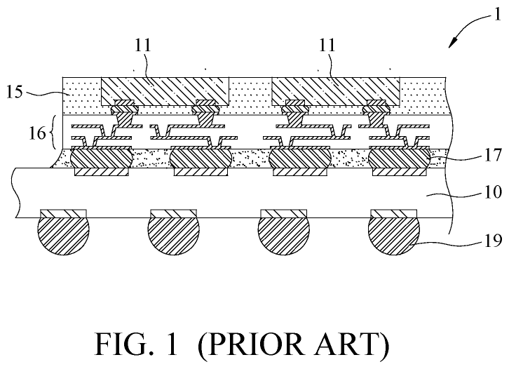

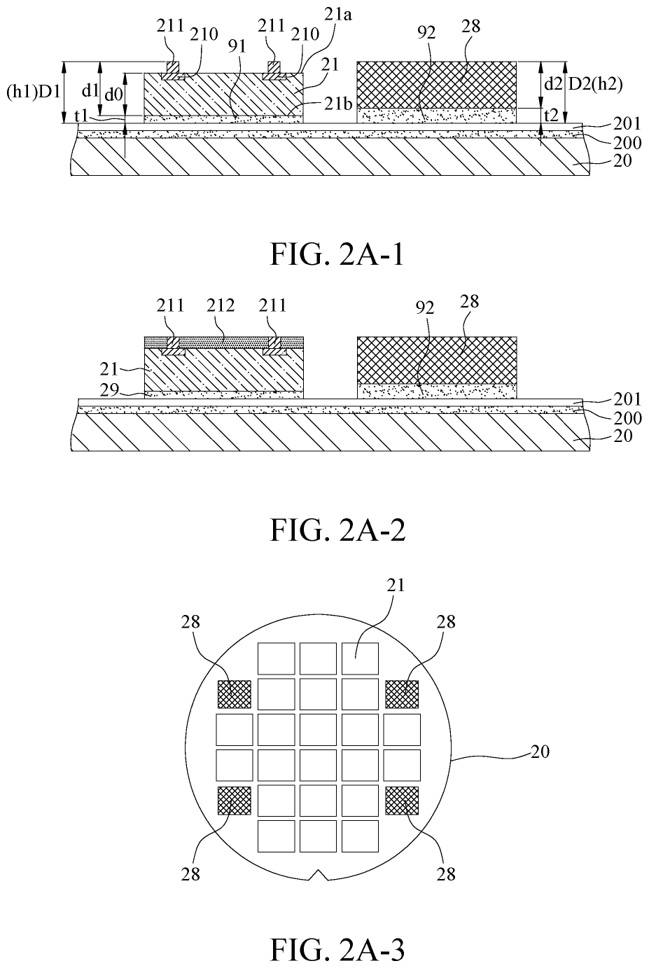

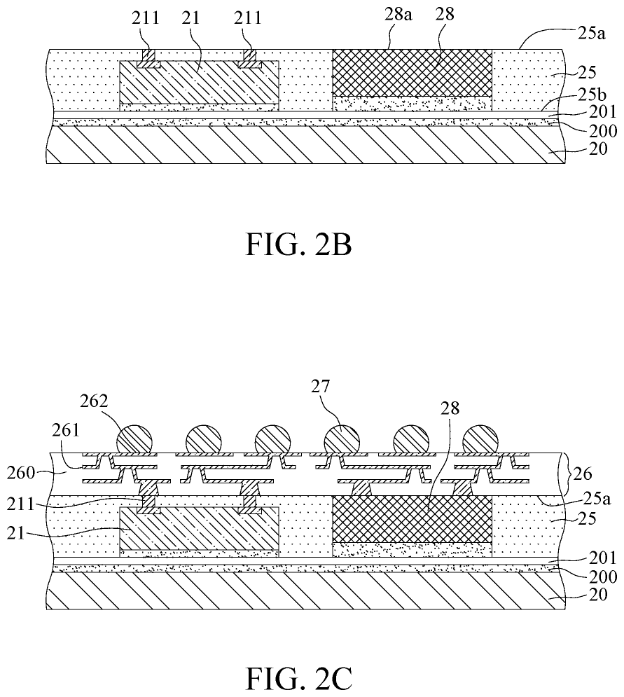

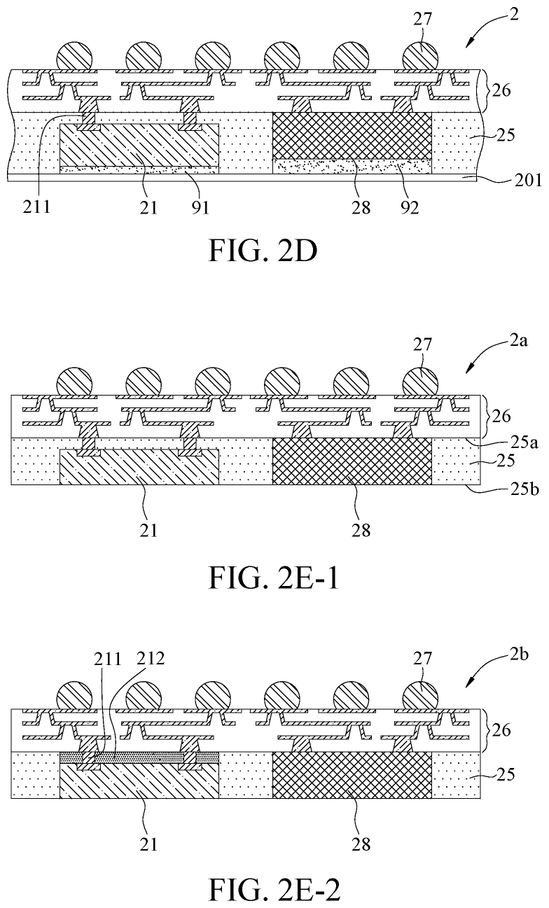

FIG. 2A-1, FIG. 2B, FIG. 2C and FIG. 2D are schematic cross-sectional views illustrating a method of manufacturing an electronic package 2 according to a first embodiment of the present disclosure.

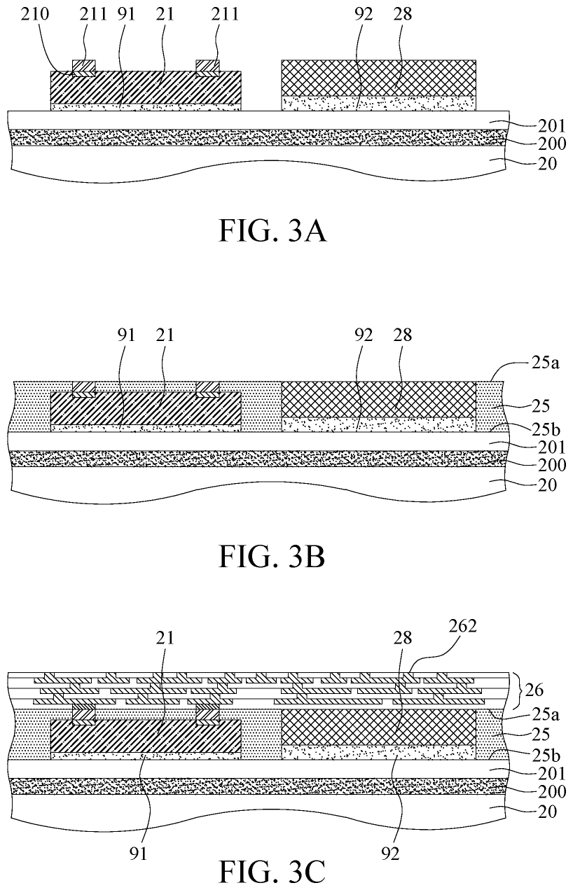

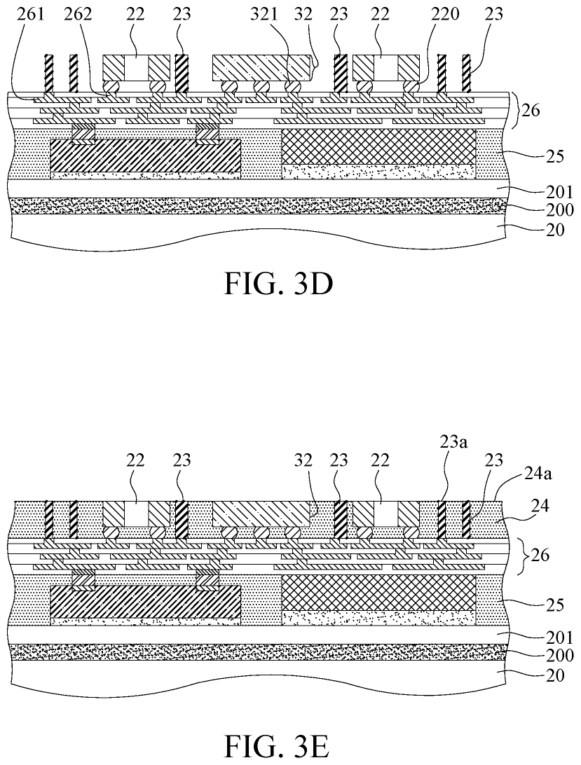

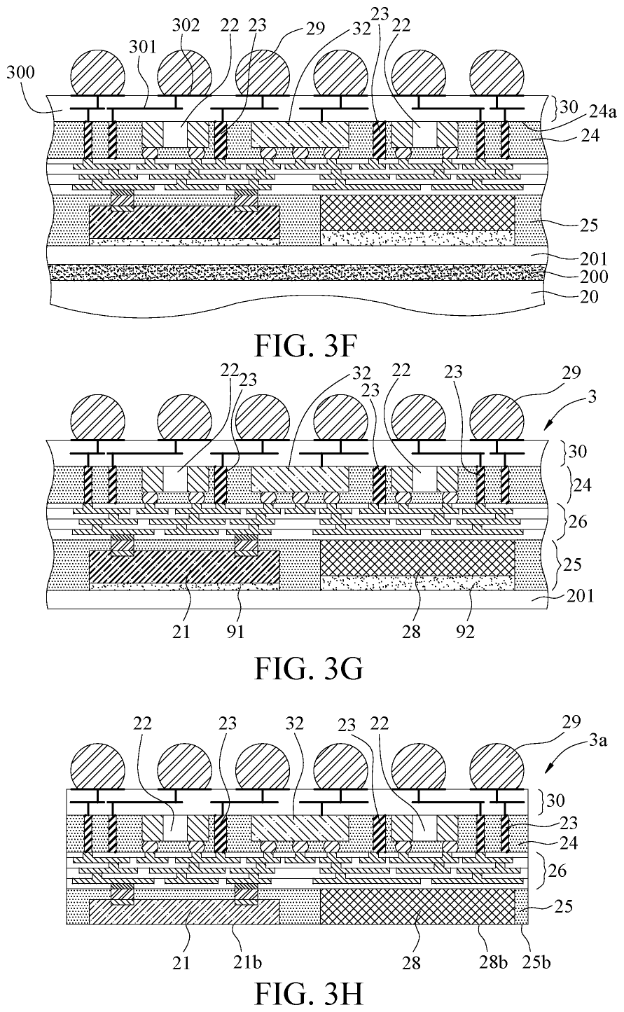

As shown in FIG. 2A-1, a plurality of first electronic elements 21 are disposed on a carrier 20 via a first bonding layer 91, and at least one dummy die 28 is disposed on the carrier 20 via a second bonding layer 92 (as shown in FIG. 2A-3, the plurality of first electronic elements 21 and a plurality of the dummy dies 28 are disposed on the carrier 20), wherein a thickness t1 of the first bonding layer 91 is less than a thickness t2 of the second bonding layer 92, and a height h1 of the first electronic element 21 relative to the carrier 20 is less than or equal to a height h2 of the dummy die 28 relative to the carrier 20.

The carrier 20 may be a metal plate or a semiconductor plate (such as a wafer or a glass plate). In an embodiment, a release layer 200 and a dielectric protection layer 201 may be sequentially formed on a surface of the carrier 20.

The first electronic element 21 is an active element, a passive element, or a combination of the active element and the passive element. The active element may be a semiconductor chip, and the passive element may be a resistor, a capacitor, or an inductor.

In an embodiment, the first electronic element 21 is a semiconductor chip, and a substrate body of the first electronic element 21 has an active surface 21a and an inactive surface 21b opposing the active surface 21a. A plurality of electrode pads 210 are formed on the active surface 21a, and the first electronic element 21 is bonded on the release layer 200 of the carrier 20 by the first bonding layer 91 with the inactive surface 21b of the first electronic element 21, and a plurality of bump-shaped conductors 211 are bonded on the plurality of electrode pads 210, so that the first electronic element 21 has a thickness d1 defined as a distance from the inactive surface 21b to end surfaces of the conductors 211.

Further, as shown in FIG. 2A-2, an insulating layer 212 covering the plurality of conductors 211 can be formed on the active surface 21a, so that a top surface of the insulating layer 212 and the end surfaces of the conductors 211 are flush with each other, and the conductors 211 are exposed from the insulating layer 212. It should be understood that the thickness d1 of the first electronic element 21 can also be defined as a distance from the inactive surface 21b to the top surface of the insulating layer 212.

Also, the insulating layer 212 is made of materials such as polybenzoxazole (PBO), polyimide (PI), prepreg (PP), or other dielectric materials.

The dummy die 28 is a semiconductor material block without signal transmission function, and a thickness d2 of the dummy die 28 is less than the thickness d1 of the first electronic element 21, so that a total thickness D2 of the dummy die 28 and the second bonding layer 92 is greater than or equal to a total thickness D1 of the first electronic element 21 and the first bonding layer 91.

In an embodiment, the thickness d2 of the dummy die 28 is equal to a thickness d0 of the substrate body of the first electronic element 21, so that the substrate body of the first electronic element 21 and the dummy die 28 can be simultaneously fabricated from the same wafer. It should be understood that the substrate body of the first electronic element 21 is formed with the conductors 211 (and the insulating layer 212) in the subsequent process, and there is no need for the dummy die 28 to form with the conductors 211 (and the insulating layer 212).

Further, the dummy die 28 is arranged according to the stress distribution in the process to prevent the carrier 20 and the overall structure on the carrier 20 from warping due to uneven stress distribution in the subsequent process. For instance, as shown in FIG. 2A-3, the dummy dies 28 are arranged at edges of the carrier 20.

In addition, the first bonding layer 91 and the second bonding layer 92 are both an aspect of a die attach film (DAF), but the present disclosure is not limited to as such.

As shown in FIG. 2B, following the process shown in FIG. 2A-1, an encapsulation layer 25 is formed on the carrier 20 to cover the first electronic element 21 and the dummy die 28.

In an embodiment, the encapsulation layer 25 has a first surface 25a and a second surface 25b opposing the first surface 25a, and the encapsulation layer 25 is bonded onto the release layer 200 of the carrier 20 with the second surface 25b of the encapsulation layer 25. For example, the encapsulation layer 25 is made of an insulating material (an encapsulating colloid such as epoxy resin) and can be formed on the carrier 20 in a manner of lamination or molding.

Further, a portion of the material of the first surface 25a of the encapsulation layer 25 is removed by a leveling process such as grinding, so that the first surface 25a of the encapsulation layer 25 is flush with the end surfaces of the conductors 211 and a surface 28a of the dummy die 28, and the conductors 211 and the dummy die 28 are exposed from the encapsulation layer 25.

It can be understood that if the process is continued with the process shown in FIG. 2A-2, the insulating layer 212 will be covered by the encapsulation layer 25, and the first surface 25a of the encapsulation layer 25 can be flush with the top surface of the insulating layer 212, so that the insulating layer 212 will also be exposed from the encapsulation layer 25.

As shown in FIG. 2C, a circuit structure 26 is formed on the first surface 25a of the encapsulation layer 25, so that the circuit structure 26 is electrically connected to the conductors 211 and transmits no signals to the dummy die 28, so there is no need for the circuit structure 26 to be electrically connected to the dummy die 28.

In an embodiment, the circuit structure 26 comprises a plurality of dielectric layers 260 and a plurality of circuit layers 261 (such as of a redistribution layer [RDL] specification) disposed on the dielectric layers 260 and electrically connected to the conductors 211. For example, a material for forming the circuit layer 261 is copper, and a material for forming the dielectric layer 260 is such as polybenzoxazole (PBO), polyimide (PI), prepreg (PP), or other dielectric materials.

Further, the circuit structure 26 may have a plurality of electrical contact pads 262 exposed from the dielectric layer 260 on the outermost circuit layer 261 for bonding conductive elements 27 such as copper pillars or solder balls, so that an electronic device (not shown, such as a package structure, a circuit board, or a chip, etc.) can be bonded to the circuit structure 26 via the conductive elements 27 in the subsequent process.

Therefore, with the configuration of the dummy die 28, the manufacturing method of the present disclosure suppresses the warpage caused by the mismatch of the coefficient of thermal expansion (CTE) between the encapsulation layer 25 and the first electronic element 21. That is, the stress in the encapsulation layer 25 can be dispersed to the dummy die 28 to improve the degree of warpage of the encapsulation layer 25, and the dummy die 28 may be arranged to a place with serious warpage (such as an edge of the circular panel of the carrier 20 as shown in FIG. 2A-3) to optimize the warpage value. Therefore, compared with the prior art, the manufacturing method of the present disclosure can prevent the carrier 20 of large full-panel or the encapsulation layer 25 from warping.

For example, due to the configuration of the dummy die 28, the degree of warpage of the encapsulation layer 25 will not increase as the size of the carrier 20 becomes larger. Therefore, when the circuit structure 26 is fabricated, the electrical connection between the circuit layer 261 and the conductors 211 of the first electronic element 21 can be effectively connected, so problems such as low yield rate and poor product reliability can be avoided so as to reduce costs and increase productivity.

Further, in the case of arranging the dummy die 28, the degree of warpage caused by the mismatch of CTE between the encapsulation layer 25 and the first electronic element 21 can be further reduced if the volume ratio of the encapsulation layer 25 is reduced, such that the anti-warping performance can be improved. Therefore, when disposing the first electronic element 21 and the dummy die 28, the dummy die 28 is bonded onto the carrier 20 by using more bonding materials, such that the thickness t2 of the second bonding layer 92 is greater than the thickness t1 of the first bonding layer 91 (that is, the amount of the second bonding layer 92 is more than the amount of the first bonding layer 91), so that the amount of the encapsulation layer 25 can be reduced to achieve a purpose of reducing the volume ratio of the encapsulation layer 25. In other words, if the conventional DAF using the same thickness is used, the volume ratio of the encapsulation layer 25 cannot be reduced.

Therefore, by adjusting the amount of the first bonding layer 91 or the second bonding layer 92, the total thickness D2 of the dummy die 28 and the second bonding layer 92 is not less than (e.g., is greater than or equal to) the total thickness D1 of the first electronic element 21 and the first bonding layer 91 (that is, the thickness t2 of the second bonding layer 92 needs to be greater than the thickness t1 of the first bonding layer 91), such that the amount of the encapsulation layer 25 can be adjusted according to requirements.

As shown in FIG. 2D, the carrier 20 and the release layer 200 on the carrier 20 are removed to expose the dielectric protection layer 201 to obtain the electronic package 2.

In an embodiment, a leveling process can be performed according to requirements in the subsequent process. As shown in FIG. 2E-1, the dielectric protection layer 201, the first bonding layer 91 and the second bonding layer 92 are removed in a manner of grinding, so that the inactive surface 21b of the first electronic element 21 and the surface of the dummy die 28 are flush with the second surface 25b of the encapsulation layer 25, such that the inactive surface 21b of the first electronic element 21 and the surface of the dummy die 28 are exposed from the second surface 25b of the encapsulation layer 25, thereby obtaining an electronic package 2a with a thinner thickness.

It should be understood that if the process is continued with the process shown in FIG. 2A-2, an electronic package 2b in which the insulating layer 212 is formed on the first electronic element 21 as shown in FIG. 2E-2 will be obtained.

Therefore, in the manufacturing method of the present disclosure, the total thickness D2 of the dummy die 28 and the second bonding layer 92 is not less than (e.g., is greater than or equal to) the total thickness D1 of the first electronic element 21 and the first bonding layer 91, so that a grinding operation performed on the dummy die 28 will grind to the dummy die 28 formed of silicon material when the encapsulation layer 25 is in the leveling process, so that the surface 28a of the silicon material with better surface roughness is exposed, thereby allowing a coating condition of the dielectric layer 260 (e.g., PI material) of the circuit structure 26 stacked on the surface 28a of the dummy die 28 in the subsequent RDL process to be better so as to effectively improve product reliability.

In other words, if the total thickness D2 of the dummy die 28 and the second bonding layer 92 is less than the total thickness D1 of the first electronic element 21 and the first bonding layer 91 (e.g., the thickness t1 of the first bonding layer 91 is equal to the thickness t2 of the second bonding layer 92), the surface 28a of the dummy die 28 will be embedded in the first surface 25a of the encapsulation layer 25 and not be exposed from the encapsulation layer 25, so when the first surface 25a of the encapsulation layer 25 is in the leveling process, the grinding operation performed to the dummy die 28 merely grinds the insulating material of the encapsulation layer 25, and the encapsulation layer 25 contains large particles of fillers which roll between the encapsulation layer 25 and the grinding tool and cause the first surface 25a of the encapsulation layer 25 located at the dummy die 28 to easily form a concave-convex surface after grinding (i.e., poor surface roughness). As a result, the coating condition of the dielectric layer 260 (e.g., PI material) of the circuit structure 26 in the subsequent RDL process is not good, thereby affecting the reliability of the product.

FIG. 3A to FIG. 3G are schematic cross-sectional views illustrating a method of manufacturing an electronic package 3 according to a second embodiment of the present disclosure. The difference between the second embodiment and the first embodiment lies in the subsequent process in FIG. 2C, so the same processes will not be repeated below.

As shown in FIG. 3A to FIG. 3C, such as the processes shown in FIG. 2A-1, FIG. 2B and FIG. 2C, the first electronic element 21 is disposed on the carrier 20 via the first bonding layer 91, and the dummy die 28 is disposed on the carrier 20 via the second bonding layer 92, and the encapsulation layer 25 is formed on the carrier 20 to cover the first electronic element 21 and the dummy die 28. Then, the circuit structure 26 is formed on the first surface 25a of the encapsulation layer 25, and the plurality of electrical contact pads 262 are formed on the outermost layer of the circuit structure 26.

As shown in FIG. 3D, a plurality of conductive pillars 23 electrically connected to the electrical contact pads 262 are formed on the circuit structure 26, and at least one (e.g., three) second electronic element 22, 32 electrically connected to the circuit layer 261 is disposed on the circuit structure 26.

In an embodiment, a material for forming the conductive pillars 23 is a metal material such as copper or a solder material, and the conductive pillars 23 are in contact with and erected (e.g., vertically disposed) on the electrical contact pads 262 by electroplating or other methods.

The second electronic elements 22, 32 comprise a semiconductor substrate, such as a passive element, a bridge die, or other elements.

In an embodiment, if the second electronic element 22 is a passive element, the second electronic element 22 is disposed on the electrical contact pads 262 and electrically connected to the circuit layer 261 via a plurality of conductive bumps 220.

Furthermore, the second electronic element 32 is a bridge die and is disposed on the electrical contact pads 262 and electrically connected to the circuit layer 261 via conductive bumps 321, wherein the conductive bumps 321 may comprise metal pillars (such as copper pillars) or solder material.

Therefore, according to circuit configuration requirements, the second electronic element 32 electrically bridges the first electronic element 21 and another electronic element (not shown) electrically connected to the circuit structure 26 via the circuit layer 261.

It should be understood that, if the second electronic element 22 is a semiconductor chip, the second electronic element 22 is disposed on the electrical contact pads 262 and electrically connected to the circuit layer 261 via the plurality of conductive bumps 220 in a flip-chip manner, and the conductive bumps 220 are covered by an underfill (not shown); alternatively, the second electronic element 22 can also be electrically connected to the electrical contact pads 262 via a plurality of bonding wires (not shown) in a wire-bonding manner. However, the manner in which the second electronic element 22 is electrically connected to the circuit layer 261 is not limited to the above.

As shown in FIG. 3E, a packaging layer 24 is formed on the circuit structure 26, such that the second electronic elements 22, 32 and the conductive pillars 23 are covered by the packaging layer 24.

In an embodiment, the packaging layer 24 is made of an insulating material, such as polyimide (PI), dry film, encapsulating colloid such as epoxy resin, or molding compound. For example, the packaging layer 24 can be formed on the circuit structure 26 in a manner of liquid compound, injection, lamination, or compression molding. It should be understood that the materials of the packaging layer 24 and the encapsulation layer 25 may be the same or different.

Furthermore, a surface 24a of the packaging layer 24 can be flush with end surfaces 23a of the conductive pillars 23 and upper surfaces of the second electronic elements 22, 32 by a leveling process, so that the end surfaces 23a of the conductive pillars 23 and the upper surfaces of the second electronic elements 22, 32 are exposed from the surface 24a of the packaging layer 24. For example, the leveling process removes a portion of the material of the conductive pillars 23 and a portion of the material of the packaging layer 24 by grinding.

As shown in FIG. 3F, a routing structure 30 (e.g., a wiring structure) is formed on the surface 24a of the packaging layer 24, and the routing structure 30 is electrically connected to the plurality of conductive pillars 23 and the second electronic element 32.

In an embodiment, the routing structure 30 comprises at least one dielectric layer 300 and at least one redistribution layer (RDL) 301 disposed on the dielectric layer 300, wherein the outermost dielectric layer 300 can be used as a solder mask layer, and the outermost redistribution layer 301 is exposed from the solder mask layer to serve as electrical contact pads 302 for bonding a plurality of conductive elements 29 such as solder balls.

Furthermore, the material for forming the redistribution layer 301 is copper, and the material for forming the dielectric layer 300 is dielectric material such as polybenzoxazole (PB 0), polyimide (PI), prepreg (PP) and the like, or solder-resist material such as solder mask (e.g., green paint), graphite (e.g., ink), etc.

As shown in FIG. 3G, the carrier 20 and the release layer 200 on the carrier 20 are removed to expose the dielectric protection layer 201 to obtain the electronic package 3.

In an embodiment, a leveling process can be performed in the subsequent process according to requirements. As shown in FIG. 3H, the dielectric protection layer 201, the first bonding layer 91 and the second bonding layer 92 are removed in a manner of grinding, so that the inactive surface 21b of the first electronic element 21 and a surface 28b of the dummy die 28 are flush with the second surface 25b of the encapsulation layer 25, such that the inactive surface 21b of the first electronic element 21 and the surface 28b of the dummy die 28 are exposed from the second surface 25b of the encapsulation layer 25, so as to obtain a thinner electronic package 3a.

It should be understood that if the process is continued with the process shown in FIG. 2A-2, an electronic package in which the insulating layer 212 is formed on the first electronic element 21 can be obtained.

Therefore, as the same reason above, it can be seen that the manufacturing method of the second embodiment also uses the configuration of the dummy die 28 to suppress the warpage caused by the mismatch of CTE between the encapsulation layer 25 and the first electronic element 21. Hence, compared with the prior art, the manufacturing method of the present disclosure can prevent the carrier 20 of large full-panel or the encapsulation layer 25 from warping.

Furthermore, since the thickness of the second bonding layer 92 is greater than the thickness of the first bonding layer 91, the amount of the encapsulation layer 25 can be reduced to reduce the volume ratio of the encapsulation layer 25, thereby further improving the anti-warping performance.

Also, since the total thickness of the dummy die 28 and the second bonding layer 92 is not less than (e.g., is greater than or equal to) the total thickness of the first electronic element 21 and the first bonding layer 91, a grinding operation is performed on the dummy die 28 to grind to the dummy die 28 formed of silicon material after the leveling process of the encapsulation layer 25 to expose the surface 28a of the silicon material with better surface roughness, thereby allowing a coating condition of the dielectric layer 260 (e.g., PI material) of the circuit structure 26 stacked on the surface 28a of the dummy die 28 in the subsequent RDL process to be better so as to effectively improve the product reliability.

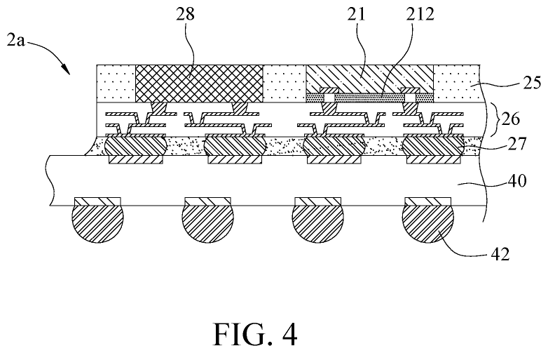

In addition, in the subsequent process of the first embodiment or the second embodiment of the present disclosure, the conductive elements 27, 29 can be disposed onto a package substrate 40, as shown in FIG. 4. For example, the electronic package 2, 2a, 2b, 3, 3a can be disposed on a top side of the package substrate 40, and a plurality of solder balls 42 can be disposed on a bottom side of the package substrate 40 for bonding an electronic device such as a circuit board (not shown).

The present disclosure further provides an electronic package 2, 2a, 2b, 3, 3a, which comprises: an encapsulation layer 25, at least one first electronic element 21, a first bonding layer 91, at least one dummy die 28, a second bonding layer 92 and a circuit structure 26.

The encapsulation layer 25 comprises a first surface 25a and a second surface 25b opposing the first surface 25a.

The first electronic element 21 is embedded in the encapsulation layer 25, wherein the first electronic element 21 has an active surface 21a and an inactive surface 21b opposing the active surface 21a, and a plurality of conductors 211 are formed on the active surface 21a, so that end surfaces of the plurality of conductors 211 are flush with the first surface 25a of the encapsulation layer 25.

The first bonding layer 91 is embedded in the encapsulation layer 25 and bonded on the inactive surface 21b, so that the first bonding layer 91 is flush with the second surface 25b of the encapsulation layer 25.

The dummy die 28 is embedded in the encapsulation layer 25 and spaced apart from the first electronic element 21, so that the surface 28a of the dummy die 28 is flush with the first surface 25a of the encapsulation layer 25.

The second bonding layer 92 is embedded in the encapsulation layer 25 and bonded on the dummy die 28, so that the second bonding layer 92 is flush with the second surface 25b of the encapsulation layer 25, wherein a thickness t1 of the first bonding layer 91 is less than a thickness t2 of the second bonding layer 92.

The circuit structure 26 is disposed on the first surface 25a of the encapsulation layer 25 and electrically connected to the first electronic element 21, and the circuit structure 26 is free from being electrically connected to the dummy die 28.

In one embodiment, the second surface 25b of the encapsulation layer 25 is bonded with a dielectric protection layer 201, so that the dielectric protection layer 201 is in contact with the first bonding layer 91 and the second bonding layer 92.

In one embodiment, a total thickness D2 of the dummy die 28 and the second bonding layer 92 is equal to a total thickness D1 of the first electronic element 21 and the first bonding layer 91.

In one embodiment, the electronic package 3, 3a further comprises second electronic elements 22, 32 disposed on and electrically connected to the circuit structure 26. For example, the second electronic elements 22, 32 are bridge elements, which electrically bridge the first electronic element 21 with another electronic element electrically connected to the circuit structure 26 via the circuit structure 26.

Furthermore, the electronic package 3, 3a further comprises conductive pillars 23 disposed on and electrically connected to the circuit structure 26. The electronic package 3, 3a also comprises a packaging layer 24 covering the conductive pillars 23 and the second electronic elements 22, 32, so that end surfaces 23a of the conductive pillars 23 are flush with a surface 24a of the packaging layer 24. The electronic package 3, 3a further comprises a routing structure 30 formed on the packaging layer 24 and electrically connected to the conductive pillars 23, so as to form a plurality of conductive elements 29 on the routing structure 30.

In one embodiment, the electronic package 2, 2a, 2b further comprises a plurality of conductive elements 27 formed on and electrically connected to the circuit structure 26.

In view of the above, in the electronic package and manufacturing method thereof according to the present disclosure, the warpage caused by the mismatch of CTE between the encapsulation layer and the first electronic element is suppressed by the configuration of the dummy die, so the present disclosure can prevent the carrier of large full-panel or the encapsulation layer from warping.

Furthermore, since the thickness of the second bonding layer is greater than the thickness of the first bonding layer, the amount of the encapsulation layer is reduced to reduce the volume ratio of the encapsulation layer, such that the anti-warping performance can be improved.

Also, since the total thickness of the dummy die and the second bonding layer is not less than (e.g., is greater than or equal to) the total thickness of the first electronic element and the first bonding layer, the grinding operation is performed on the dummy die to grind to the dummy die formed of the silicon material after the leveling process of the encapsulation layer to expose the surface of the silicon material with better surface roughness, thereby allowing a coating condition of the dielectric layer (e.g., PI material) of the circuit structure stacked on the surface of the dummy die in the subsequent RDL process to be better so as to effectively improve the product reliability. The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
an encapsulation layer having a first surface and a second surface opposing the first surface;
a first electronic element embedded in the encapsulation layer, wherein the first electronic element has an active surface and an inactive surface opposing the active surface, wherein the active surface has a plurality of conductors, and surfaces of the conductors are flush with the first surface of the encapsulation layer;
a first bonding layer embedded in the encapsulation layer and bonded on the inactive surface, wherein an outer surface of the first bonding layer is flush with the second surface of the encapsulation layer;
a dummy die embedded in the encapsulation layer and spaced apart from the first electronic element, wherein a surface of the dummy die is flush with the first surface of the encapsulation layer;
a second bonding layer embedded in the encapsulation layer and bonded on the dummy die, wherein an outer surface of the second bonding layer is flush with the second surface of the encapsulation layer, wherein a thickness of the first bonding layer is less than a thickness of the second bonding layer; and
a circuit structure disposed on the first surface of the encapsulation layer and electrically connected to the first electronic element.

2. The electronic package of claim 1, wherein the second surface of the encapsulation layer is bonded with a dielectric protection layer, and the dielectric protection layer is in contact with the first bonding layer and the second bonding layer.

3. The electronic package of claim 1, further comprising a second electronic element disposed on and electrically connected to the circuit structure.

4. The electronic package of claim 3, wherein the second electronic element is a bridge element for electrically bridging the first electronic element and another electronic element electrically connected to the circuit structure via the circuit structure.

5. The electronic package of claim 3, further comprising conductive pillars disposed on and electrically connected to the circuit structure.

6. The electronic package of claim 5, further comprising a packaging layer covering the conductive pillars and the second electronic element, wherein end surfaces of the conductive pillars are flush with a surface of the packaging layer.

7. The electronic package of claim 6, further comprising a routing structure formed on the packaging layer and electrically connected to the conductive pillars.

8. The electronic package of claim 7, further comprising a plurality of conductive elements formed on the routing structure.

9. The electronic package of claim 1, further comprising a plurality of conductive elements formed on the circuit structure.

10. A method of manufacturing an electronic package, comprising:
disposing a first electronic element on a carrier via a first bonding layer, and disposing a dummy die on the carrier via a second bonding layer, the first electronic element and the dummy die being spaced apart from each other, wherein the first electronic element has an active surface and an inactive surface opposing the active surface, the active surface has a plurality of conductors, and the first electronic element is bonded with the first bonding layer by the inactive surface of the first electronic element, wherein a thickness of the first bonding layer is less than a thickness of the second bonding layer, wherein a height of the first electronic element relative to the carrier is less than or equal to a height of the dummy die relative to the carrier;
forming an encapsulation layer on the carrier, wherein the first electronic element and the dummy die are covered by the encapsulation layer, wherein the encapsulation layer has a first surface and a second surface opposing the first surface, and the encapsulation layer is bonded onto the carrier with the second surface of the encapsulation layer, wherein end surfaces of the plurality of conductors and a surface of the dummy die are flush with the first surface of the encapsulation layer;
forming a circuit structure on the first surface of the encapsulation layer, wherein the circuit structure is electrically connected to the conductors of the first electronic element and free from being electrically connected to the dummy die; and
removing the carrier, wherein an outer surface of the first bonding layer and an outer surface of the second bonding layer are flush with the second surface of the encapsulation layer.

11. The method of claim 10, wherein the carrier is in contact with and bonded to the second surface of the encapsulation layer, the first bonding layer and the second bonding layer via a dielectric protection layer.

12. The method of claim 10, further comprising disposing a second electronic element on the circuit structure, wherein the second electronic element is electrically connected to the circuit structure.

13. The method of claim 12, wherein the second electronic element is a bridge element for electrically bridging the first electronic element and another electronic element electrically connected to the circuit structure via the circuit structure.

14. The method of claim 12, further comprising forming conductive pillars on the circuit structure, wherein the conductive pillars are electrically connected to the circuit structure.

15. The method of claim 14, further comprising covering the conductive pillars and the second electronic element by a packaging layer, wherein end surfaces of the conductive pillars are exposed from the packaging layer.

16. The method of claim 15, further comprising forming a routing structure on the packaging layer, wherein the routing structure is electrically connected to the conductive pillars.

17. The method of claim 16, further comprising forming a plurality of conductive elements on the routing structure.

18. The method of claim 10, further comprising forming a plurality of conductive elements on the circuit structure.
